(19) United States
(12) Patent Application Publication
(10) Pub. No.: US 2015/0128860 A1
(43) Pub. Date: May 14, 2015

(54) DEPOSITION SYSTEMS HAVING DEPOSITION CHAMBERS CONFIGURED FOR IN-SITU METROLOGY WITH RADIATION DEFLECTION AND RELATED METHODS

(71) Applicant: Soitec, Crolles Cedex (FR)

(72) Inventors: Claudio Canizares, Chandler, AZ (US); Ding Ding, Chandler, AZ (US)

(73) Assignee: Soitec, Crolles Cedex (FR)

(21) Appl. No.: 14/401,261

(22) PCT Filed: May 24, 2013
(86) PCT No.: PCT/IB2013/001056

§ 371 Date: Nov. 14, 2014

Related U.S. Application Data
(60) Provisional application No. 61/656,946, filed on Jun. 7, 2012.

(51) Int. Cl. C23C 16/48; C30B 25/08; C23C 16/52

(52) U.S. Cl. CPC C23C 16/48; C23C 16/52; C30B 25/08
USPC 118/712; 29/592; 118/715

(57) ABSTRACT

Deposition chambers (102) for use with deposition systems (100) include a chamber wall (112) comprising a transparent material. The chamber wall may include an outer metrology window (122) surface extending from and at least partially circumscribed by an outer major surface of the wall, and an inner metrology window surface extending from and at least partially circumscribed by an inner major surface of the wall. The window surfaces may be oriented at angles to the major surfaces. Deposition systems include such chambers. Methods include the formation of such deposition chambers. The depositions systems and chambers may be used to perform in-situ metrology.

### CROSS-REFERENCE TO RELATED APPLICATIONS

This application is a national phase entry under 35 U.S.C. §371 of International Patent Application PCT/IB2013/001056, filed May 24, 2013, designating the United States of America and published in English as International Patent Publication WO2013/182880 A2 on Dec. 12, 2013, which claims the benefit under Article 8 of the Patent Cooperation Treaty to the U.S. Provisional Application Ser. No. 61/656,946, filed Jun. 7, 2012, the disclosures of which are hereby incorporated herein in their entireties by this reference. The subject matter of this application is related to the subject matter of U.S. patent application Ser. No. 13/327,302, which was filed Dec. 15, 2011 in the name of Lindow et al. and entitled “DEPOSITION SYSTEMS HAVING DEPOSITION CHAMBERS CONFIGURED FOR IN-SITU METROLOGY AND RELATED METHODS,” the disclosure of which is hereby incorporated herein in its entirety by this reference.

### FIELD

Embodiments of the invention generally relate to systems for depositing materials on substrates, and to methods of making and using such systems. More particularly, embodiments of the invention relate to deposition chambers that are configured for use with in-situ metrology systems, and to methods of performing in-situ metrology during a deposition process carried out within such a deposition chamber.

### BACKGROUND

Various types of deposition processes are used to deposit materials on substrates in deposition chambers. For example, chemical vapor deposition (CVD) is a chemical process that is used to deposit solid materials on substrates, and is commonly employed in the manufacture of semiconductor devices. In chemical vapor deposition processes, a substrate is exposed to one or more reagent gases, which react, decompose, or both react and decompose in a manner that results in the deposition of a solid material on the surface of the substrate.

One particular type of CVD process is referred to in the art as vapor phase epitaxy (VPE). In VPE processes, a substrate is exposed to one or more reagent vapors in a deposition chamber, which react, decompose, or both react and decompose, in a manner that results in the epitaxial deposition of a solid material on the surface of the substrate. VPE processes are often used to deposit III-V semiconductor materials. When one of the reagent vapors in a VPE process comprises a hydride vapor, the process may be referred to as a hydride vapor phase epitaxy (HVPE) process.

HVPE processes are used to form III-V semiconductor materials such as, for example, gallium nitride (GaN). In such processes, epitaxial growth of GaN on a substrate results from a vapor phase reaction between gallium chloride (GaCl) and ammonia (NH₃) that is carried out within a deposition chamber at elevated temperatures between about 500° C. and about 1100° C. The NH₃ may be supplied from a standard source of NH₃ gas.

In-situ metrology systems are used in deposition systems to monitor in real-time characteristics of a material being deposited, such as a semiconductor material being deposited on a substrate.

For example, in-situ metrology systems may be used to monitor a thickness of a layer of material being deposited, a growth rate of a layer of material being deposited (often expressed in terms of change in layer thickness per unit time), a temperature of a layer of material being deposited, or bow (i.e., curvature) of a layer of material being deposited during the deposition process.

In-situ metrology systems may comprise source of radiation (e.g., electromagnetic radiation) and a sensor for receiving and detecting radiation emitted by the receiver after the radiation interacts (e.g., reflects from) in some way with the layer of material being deposited. The radiation emitted from the source may be emitted at a selected wavelength and directed toward the growth substrate upon which material is being deposited during the deposition process. One or more characteristics of the radiation received and detected by the sensor subsequent to interaction with the material being deposited may provide information related to one or more characteristics of the material being deposited.

### BRIEF SUMMARY

This summary is provided to introduce a selection of concepts in a simplified form, such concepts being further described in the detailed description below of some example embodiments of the invention. This summary is not intended to identify key features or essential features of the claimed subject matter, nor is it intended to be used to limit the scope of the claimed subject matter.

In some embodiments, the present disclosure includes deposition chambers for use with deposition systems. For example, a deposition chamber may include at least one chamber wall including a transparent material at least substantially transparent to electromagnetic radiation over at least a range of wavelengths. The at least one chamber wall may comprise an outer major surface and an inner major surface oriented at least substantially parallel to the outer major surface. The chamber wall may further include an outer window surface extending from and at least partially circumscribed by the outer major surface, and an inner window surface extending from and at least partially circumscribed by the inner major surface. The outer window surface may be oriented at an angle to the outer major surface, and the inner window surface may be oriented at an angle to the inner major surface. At least a portion of the inner window surface may be aligned with at least a portion of the outer window surface along an axis perpendicular to the outer major surface and the inner major surface.

In additional embodiments, the present disclosure includes deposition systems that include such a deposition chamber and at least one metrology device. The metrology device may include an emitter and a sensor, each located outside the deposition chamber. The emitter is configured to emit radiation at one or more wavelengths through each of the outer window surface and the inner window surface of a chamber wall, and the sensor is configured to receive electromagnetic radiation emitted by the emitter and reflected from a location within the deposition chamber.

In additional embodiments, the present disclosure includes methods of forming deposition chambers as described herein. For example, at least one chamber wall may be formed that includes a transparent material at least substantially transparent to electromagnetic radiation over at least a range of wavelengths. In forming the at least one chamber wall, an outer major surface of the at least one chamber wall may be formed, and an inner major surface of the at least one chamber wall may be formed that is oriented at least substantially parallel to the outer major surface. An outer window surface of the at least one chamber wall may be formed that extends from and is at least partially circumscribed by the outer major surface. The outer window surface may be oriented at an angle to the outer major surface. An inner window surface of the at least one chamber wall may be formed that extends from and is at least partially circumscribed by the inner major surface. The inner window surface may be oriented at an angle to the inner major surface. At least a portion of the inner window surface may be aligned with at least a portion of the outer window surface along an axis perpendicular to the outer major surface and the inner major surface.

In yet further embodiments, the present disclosure includes methods of performing in-situ metrology while depositing material on a substrate using a deposition system. The deposition system and/or deposition chamber may be as described herein. For example, at least one substrate may be positioned within an interior of a deposition chamber. Radiation may be emitted from an emitter of a metrology device from a location outside the deposition chamber, through a metrology window in at least one chamber wall of the deposition chamber and toward the at least one substrate. The at least one chamber wall may comprise an outer major surface and an inner major surface oriented at least substantially parallel to the outer major surface. Radiation emitted by the emitter may be sensed after the radiation interacts with a material being deposited on the substrate using a sensor located outside the deposition chamber. Emitting radiation from the emitter through the metrology window in the at least one chamber wall may comprise passing the emitted radiation through an outer window surface of the at least one chamber wall extending from and at least partially circumscribed by the outer major surface, and passing the emitted radiation through an inner window surface of the at least one chamber wall extending from and at least partially circumscribed by the inner major surface. The outer window surface may be oriented at an angle to the outer major surface, and the inner window surface may be oriented at an angle to the inner major surface. At least a portion of the inner window surface may be aligned with at least a portion of the outer window surface along an axis perpendicular to the outer major surface and the inner major surface.

### BRIEF DESCRIPTION OF THE DRAWINGS

The present disclosure may be understood more fully by reference to the following detailed description of example embodiments, which are illustrated in the appended figures in which:

FIG. 1 is a cut-away perspective view schematically illustrating an example embodiment of a deposition system that includes a deposition chamber having at least one chamber wall that includes metrology windows configured as described herein through which radiation emitted by an emitter of a metrology system may pass while performing in-situ metrology on a material being deposited on a substrate within the deposition chamber;

FIG. 2 is a top plan view of a deposition chamber similar to the deposition chamber schematically illustrated in FIG. 1;

FIG. 3 is a side plan view of the deposition chamber of FIG. 2;

FIG. 4 is a bottom plan view of the deposition chamber of FIGS. 2 and 3;

FIG. 5 is a top plan view of a top chamber wall of the deposition chamber of FIGS. 2 through 4;

FIG. 6 is a bottom plan view of the chamber wall shown in FIG. 5;

FIG. 7 is an enlarged cross-sectional view of a portion of the chamber wall of FIGS. 5 and 6 taken through a metrology window formed in the chamber wall and illustrating an outer winder surface and an inner window surface;

FIG. 8 is a schematic representation of radiation emitted by an emitter of a metrology device passing through a metrology window of a chamber wall, such as the metrology window of the chamber wall illustrated in FIG. 7; and

FIG. 9 is a schematic representation of radiation emitted by an emitter of a metrology device passing through a conventional planar chamber wall.

### DETAILED DESCRIPTION

The illustrations presented herein are not meant to be actual views of any particular system, component, or device, but are merely idealized representations that are employed to describe embodiments of the present invention.

As used herein, the term “III-V semiconductor material” means and includes any semiconductor material that is at least predominantly comprised of one or more elements from group IIIA of the periodic table (B, Al, Ga, In, and Tl) and one or more elements from group VA of the periodic table (N, P, As, Sb, and Bi). For example, III-V semiconductor materials include, but are not limited to, GaN, GaP, GaAs, InN, InP, InAs, AlN, AlP, AlAs, InGaN, InGaP, InGaNP, etc.

As used herein, the term “gas” includes gases (fluids that have neither independent shape nor volume) and vapors (gases that include diffused liquid or solid matter suspended therein), and the terms “gas” and “vapor” are used synonymously herein.

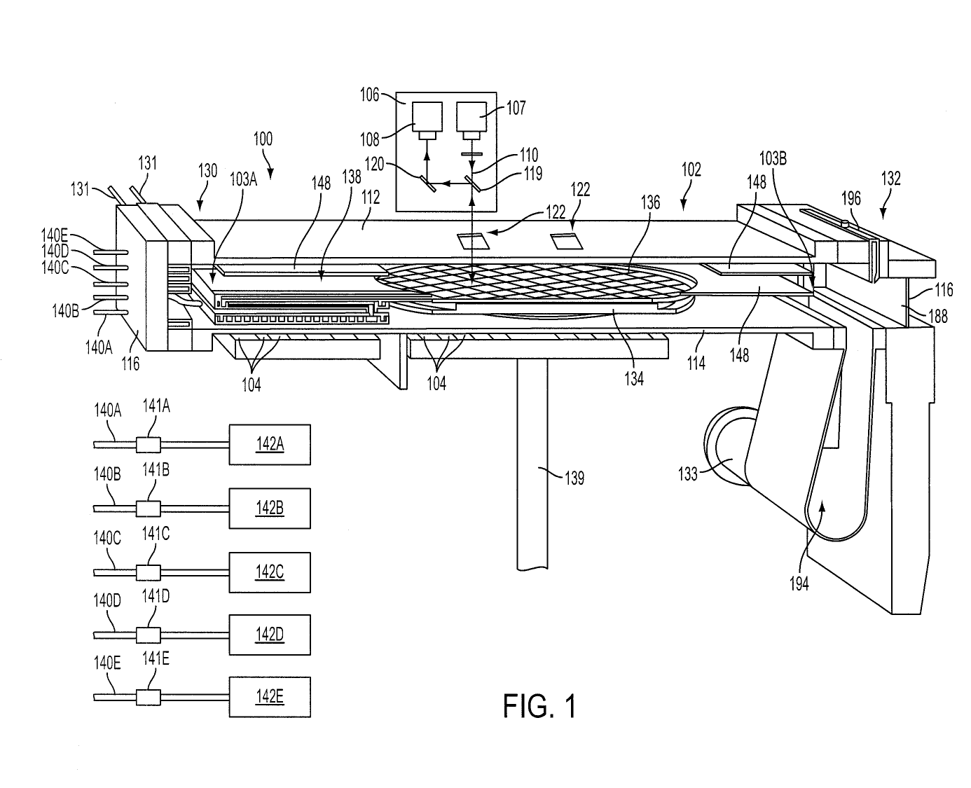

FIG. 1 illustrates an example of a deposition system 100 in accordance with the present disclosure. In some embodiments, the deposition system 100 may comprise a CVD system, such as a VPE deposition system (e.g., an HVPE deposition system). The deposition system 100 includes an at least substantially enclosed deposition chamber 102, and a metrology device 106 for performing in-situ metrology on layers of material to be deposited on one or more substrates within the deposition chamber 102 during deposition processes. The metrology device 106 includes at least one emitter 107 for emitting radiation 110 toward a substrate within the chamber 102, and at least one sensor 108 for sensing radiation emitted by the emitter 107 and reflected from the substrate (or a material being deposited over the substrate) within the chamber 102.

The deposition chamber 102 may include one or more chamber walls. For example, the chamber walls may include a horizontally oriented top chamber wall 112, a horizontally oriented bottom chamber wall 114, and one or more vertically oriented lateral side chamber walls 116 extending between the top chamber wall 112 and the bottom chamber wall 114.

As discussed subsequently herein in further detail, the deposition chamber 102 includes at least one chamber wall, such as a top chamber wall 112, including one or more selectively configured metrology windows 122 through which radiation 110 emitted by the emitter 107 and/or received by the sensor 108 may pass during in-situ metrology performed using the metrology device 106.

The deposition system 100 may include a gas injection device 130 used for injecting one or more process gases into the deposition chamber 102, and a venting and loading subassembly 132 used for venting process gases out from the deposition chamber 102 and for loading substrates into the deposition chamber 102 and unloading substrates out from the deposition chamber 102. The gas injection device 130 may be configured to inject one or more process gases through one or more of the lateral side walls 116 of the deposition chamber 102.

In some embodiments, the deposition chamber 102 may have the geometric shape of an elongated rectangular prism, as shown in FIG. 1. In some such embodiments, the gas injection device 130 may be located at a first end of the deposition chamber 102, and the venting and loading subassembly may be located at an opposing, second end of the deposition chamber 102, wherein the elongated longitudinal direction is the direction extending between the first end of the deposition chamber at which the gas injection device 130 is located and the opposing, second end of the deposition chamber 102 at which the venting and loading subassembly is located. In other embodiments, the deposition chamber 102 may have another geometric shape.

The deposition system 100 includes a substrate support structure 134 (e.g., a susceptor) configured to support one or more substrates 136 on which it is desired to deposit or otherwise provide semiconductor material within the deposition system 100. For example, the one or more substrates 136 may comprise dies or wafers. As shown in FIG. 1, the substrate support structure 134 may be coupled to a spindle 139, which may be coupled (e.g., directly structurally coupled, magnetically coupled, etc.) to a drive device (not shown), such as an electrical motor that is configured to drive rotation of the spindle 139 and, hence, the substrate support structure 134 within the deposition chamber 102.

The deposition system 100 further includes a gas flow system used to flow process gases through the deposition chamber 102. For example, the deposition system 100 may comprise at least one gas injection device 130 for injecting one or more process gases into the deposition chamber 102 at a first location 103A, and a vacuum device 133 for drawing the one or more process gases through the deposition chamber 102 from the first location 103A to a second location 103B and for evacuating the one or more process gases out from the deposition chamber 102 at the second location 103B. The gas injection device 130 may comprise, for example, a gas injection manifold including connectors configured to couple with conduits carrying one or more process gases from process gas sources.

With continued reference to FIG. 1, the deposition system 100 may include gas inflow conduits 140A-140E that carry gases from respective process gas sources 142A-142E to the gas injection device 130. Optionally, gas valves (141A-141E) may be used to selectively control the flow of gas through the gas inflow conduits 140A-140E, respectively. In some embodiments, the temperatures of the gas inflow conduits 140A-140E may be controlled between the gas sources 142A-142E and the deposition chamber 102. The temperatures of the gas inflow conduits 140A-140E and associated mass flow sensors, controllers, and the like, may increase gradually from a first temperature (e.g., about 100° C. or more) at the exit from the respective gas sources 142A-142E up to a second temperature (e.g., about 150° C. or less) at the point of entry into the deposition chamber 102 in order to prevent condensation of the gases in the gas inflow conduits 140A-140E. The pressure of the source gases may be controlled using one or more pressure control systems. While the illustrated deposition system 100 includes five gas inflow conduits and respective gas sources, the deposition system 100 may include less than five (e.g., one to four) gas inflow conduits and respective gas sources, or the deposition system 100 may include more than five (e.g., six, seven, etc.) gas inflow conduits and respective gas sources in additional embodiments.

The gas inflow conduits 140A-140E extend to the gas injection device 130. The gas injection device 130 may comprise one or more blocks of material through which the process gases are carried into the deposition chamber 102. One or more cooling conduits 131 may extend through the blocks of material. A cooling fluid may be caused to flow through the one or more cooling conduits 131 so as to maintain the gas or gases flowing through the gas injection device 130 by way of the gas inflow conduits 140A-140E within a desirable temperature range during operation of the deposition system 100. For example, it may be desirable to maintain the gas or gases flowing through the gas injection device 130 by way of the gas inflow conduits 140A-140E at a temperature less than about 200° C. (e.g., about 150° C.) during operation of the deposition system 100. Optionally, the deposition system 100 may include an interior precursor gas furnace 138, as described in provisional U.S. Patent Application Ser. No. 61/526,143, which was filed Aug. 22, 2011 in the name of Bertram et al. and titled “DEPOSITION SYSTEMS INCLUDING A PRECURSOR GAS FURNACE WITHIN A DEPOSITION CHAMBER, AND RELATED METHODS,” the disclosure of which is hereby incorporated herein in its entirety by this reference.

With continued reference to FIG. 1, the venting and loading subassembly 132 may comprise a vacuum chamber 194 into which gases flowing through the deposition chamber 102 are drawn by a vacuum within the vacuum chamber 194 and vented out from the deposition chamber 102. The vacuum within the vacuum chamber 194 is generated by the vacuum device 133. As shown in FIG. 1, the vacuum chamber 194 may be located below the deposition chamber 102. The venting and loading subassembly 132 may further comprise a purge gas curtain device 196 that is configured and oriented to provide a generally planar curtain of flowing purge gas, which flows out from the purge gas curtain device 196 and into the vacuum chamber 194. The venting and loading subassembly 132 also may include an access gate 188, which may be selectively opened for loading and/or unloading substrates 136 from the substrate support structure 134, and selectively closed for processing of the substrates 136 using the deposition system 100. In some embodiments, the access gate 188 may comprise at least one plate configured to move between a closed first position and an open second position. The access gate 188 may extend through a side wall of the deposition chamber 102 in some embodiments.

The deposition chamber 102 may be at least substantially enclosed, and access to the substrate support structure 134 through the access gate 188 may be precluded when the plate of the access gate 188 is in the closed first position. Access to the substrate support structure 134 may be enabled through the access gate 188 when the plate of the access gate 188 is in the open, second position. The purge gas curtain emitted by the purge gas curtain device 196 may reduce or prevent the flow of gases out from the deposition chamber 102 during loading and/or unloading of substrates 136. Gaseous byproducts, carrier gases, and any excess precursor gases may be exhausted out from the deposition chamber 102 through the venting and loading subassembly 132.

The deposition system 100 may comprise a plurality of thermal radiation emitters 104, as illustrated in FIG. 1. The thermal radiation emitters 104 are configured to emit thermal radiation within a range of wavelengths of electromagnetic radiation in at least one of the infrared region and the visible region of the electromagnetic radiation spectrum. For example, the thermal radiation emitters 104 may comprise thermal lamps (not shown) configured to emit thermal energy in the form of electromagnetic radiation. In some embodiments, the thermal radiation emitters 104 may be located outside and below the deposition chamber 102 adjacent the bottom wall 114. In additional embodiments, the thermal radiation emitters 104 may be located above the deposition chamber 102 adjacent the top wall 112, beside the deposition chamber 102 adjacent one or more lateral side walls 116, or at a combination of such locations. The thermal radiation emitters 104 may be disposed in a plurality of rows of thermal radiation emitters 104, which may be controlled independently from one another. In other words, the thermal energy emitted by each row of thermal radiation emitters 104 may be independently controllable. The rows may be oriented transverse to the direction of the net flow of gas through the deposition chamber 102, which is the direction extending from left to right from the perspective of FIG. 1. Thus, the independently controlled rows of thermal radiation emitters 104 may be used to provide a selected thermal gradient across the interior of the deposition chamber 102, if so desired.

The thermal radiation emitters 104 may be located outside the deposition chamber 102 and configured to emit thermal radiation through at least one chamber wall of the deposition chamber 102 and into an interior of the deposition chamber 102. Thus, at least a portion of the chamber walls through which the thermal radiation is to pass into the deposition chamber 102 may comprise a transparent material, so as to allow efficient transmission of the thermal radiation into the interior of the deposition chamber 102. The transparent material may be transparent in the sense that the material may be at least substantially transparent to electromagnetic radiation at wavelengths corresponding to the thermal radiation emitted by the thermal radiation emitters 104.

As a non-limiting example, the transparent material may comprise a transparent refractory ceramic material, such as transparent quartz (i.e., silicon dioxide (SiO₂)). The transparent quartz may be fused quartz, and may have an amorphous or crystalline microstructure. Any other refractory material that is both physically and chemically stable at the temperatures and in the environments to which the material is subjected during deposition processes using the deposition system 100, and that is sufficiently transparent to the thermal radiation emitted by the thermal radiation emitters 104, may be used to form one or more of the chamber walls of the deposition system 100 in further embodiments of the disclosure.

As shown in FIG. 1, in some embodiments, the thermal radiation emitters 104 may be disposed outside and below the deposition chamber 102 adjacent the bottom wall 114 of the deposition chamber 102. In such embodiments, the bottom wall 114 may comprise a transparent material, such as transparent quartz, so as to allow transmission of the thermal radiation emitted by the thermal radiation emitters 104 into the interior of the deposition chamber 102 as described above. Of course, thermal radiation emitters 104 may be provided adjacent other chamber walls of the deposition chamber 102 and at least a portion of such chamber walls also may comprise a transparent material as described herein.

With continued reference to FIG. 1, in some embodiments, one or more opaque bodies 148, each comprising a volume of an opaque material, may be positioned within the interior of the deposition chamber 102 for reducing (e.g., minimizing) impingement of thermal radiation emitted by the thermal radiation emitters 104 on the sensor 108 of the metrology device 106, as described in U.S. patent application Ser. No. 13/327,302, which was filed Dec. 15, 2011 in the name of Lindow et al., which was previously incorporated by reference. The one or more opaque bodies 148 may comprise generally planar plate-shaped structures in some embodiments. In such embodiments, the generally planar plate-shaped structures may be horizontally oriented such that they extend generally parallel to the top wall 112 and the bottom wall 114, as shown in FIG. 1. The one or more opaque bodies 148 may be disposed between the top wall 112 and the bottom wall 114, and may be located and oriented to shield the sensor or sensors 108 from at least some of the thermal radiation emitted by the thermal radiation emitters 104. For example, a generally planar plate-shaped opaque body 148 may be located over the interior precursor gas furnace 148 proximate to the gas injection device 130, and additional generally planar plate-shaped opaque bodies 138 may be located proximate to the venting and loading subassembly 132, as shown in FIG. 1.

Further, at least a portion of one or more of the chamber walls may comprise a volume of opaque material, as also described in U.S. patent application Ser. No. 13/327,302, which was filed Dec. 15, 2011 in the name of Lindow et al., previously incorporated by reference, for shielding the sensor 108 of the metrology device 106 from electromagnetic radiation emitted by the thermal radiation emitters 104. The volumes of opaque material of the chamber walls may be integral portions of the chamber walls, or they may comprise, for example, plates or other bodies of opaque material that are simply disposed adjacent, and optionally bonded to, the respective chamber walls.

The configuration and arrangement of the various components of the deposition system described above are set forth as non-limiting examples, and embodiments of the present invention include other arrangements and configurations of components.

With continued reference to FIG. 1, as previously mentioned, the deposition system 100 may comprise at least one metrology device 106 for detecting and/or measuring one or more characteristics of a substrate 136, or a material deposited on the substrate 136, in situ within the interior of the deposition chamber 102. The metrology device 106 may include, for example, one or more of a reflectometer, a deflectometer, and a pyrometer. Reflectometers are often used in the art to measure, for example, a growth rate and/or a topography of material being deposited on the substrate 136 in the deposition chamber 102. Deflectometers are often used in the art to measure planarity or non-planarity (e.g., bow) of the substrate 136 (and/or a material being deposited thereon). Pyrometers are often used in the art to measure a temperature of the substrate 136 within the deposition chamber 102. In some embodiments, the metrology device 106 may comprise a multi-beam optical sensor (MOS), such as a multi-beam optical stress sensor (MOSS).

The metrology device 106 includes an emitter 107 and a sensor 108, each of which may be located outside the deposition chamber 102. The emitter 107 is configured to emit radiation (e.g., electromagnetic radiation) at one or more wavelengths. As previously mentioned, at least one of the chamber walls, such as the top chamber wall 112, of the deposition chamber 102 may comprise a transparent material, such as quartz, that is at least substantially transparent to electromagnetic radiation over at least a range of wavelengths. The wavelength or wavelengths of radiation emitted by the emitter 107 of the metrology device 106 may be within the range of wavelengths to which the material of the chamber wall is transparent, so as to allow the radiation emitted by the emitter 107 to pass through the chamber wall. The sensor 108 of the metrology device 106 is configured to receive and detect electromagnetic radiation emitted by the emitter 107 and reflected from a location within the deposition chamber, such as from a substrate 136 or a material being deposited on the substrate 136 (e.g., a layer of semiconductor material). Thus, the metrology device 106 may emit electromagnetic radiation toward the substrate 136 or a material on the substrate, while detecting the emitted electromagnetic radiation after it has been reflected from the substrate 136 or a material thereon.

As one particular non-limiting example embodiment, the metrology device 106 may comprise a multi-beam optical stress sensor (MOSS) having the general configuration that is schematically illustrated in FIG. 1. As shown in FIG. 1, an emitter 107 may comprise a laser configured to emit a beam of at least substantially coherent electromagnetic laser radiation. The laser beam emitted by the emitter 107 may pass through an etalon beam splitter, which may split the beam of laser radiation into three separate laser beams extending at least substantially parallel to one another. The three laser beams may pass through one or more beam splitters, such as the beam splitter 119, which may be configured to allow specific wavelengths of radiation to pass through the beam splitter 119 while reflecting other wavelengths. The wavelengths of the three laser beams that pass through the beam splitter 119 may pass through a metrology window 122 as described herein and into the interior of the deposition chamber 102. The laser radiation impinges on, and is reflected from, a substrate 136 or a material being deposited on the substrate 136. The reflected laser radiation then passes again through the metrology window 122 to the exterior of the deposition chamber 102. The reflected laser radiation impacts and is redirected (e.g., reflected) from the beam splitter 119 and onto a monochromatic beam splitter 120, which directs the reflected radiation to the sensor 108. The sensor 108 receives and detects the radiation reflected from the substrate 136 or a material being deposited on the substrate 136, and generates one or more electrical signals. The electrical signals may include one or more characteristics that may be used to extract information relating to one or more characteristics of the substrate 136 or a material being deposited on the substrate 136.

One or more of the chamber walls, such as the top chamber wall 112, may include one or more optical metrology windows 122 through which the radiation emitted and/or received by the metrology device 106 may pass into and/or out from the deposition chamber 102. The metrology windows 122 may be as described in further detail herein below.

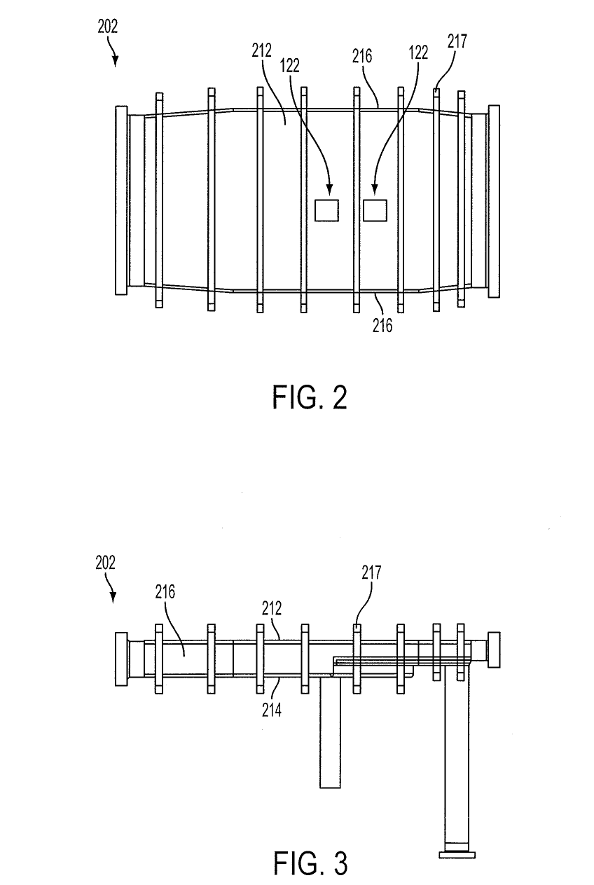

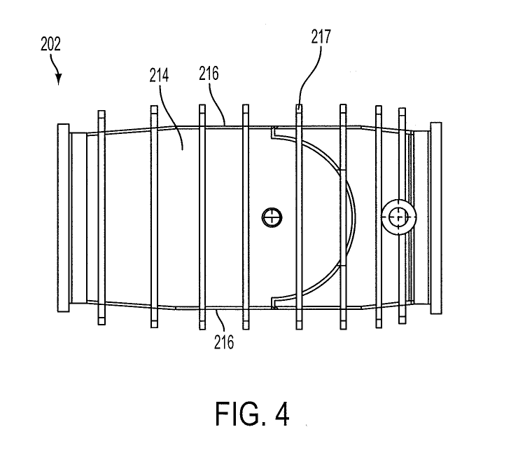

FIGS. 2 through 4 illustrate another example embodiment of a deposition chamber 202 according to embodiments of the present disclosure, which include one or more optical metrology windows 122 therein.

The deposition chamber 202 may include one or more chamber walls. For example, the chamber walls may include a horizontally oriented top chamber wall 212, a horizontally oriented bottom chamber wall 214, and one or more vertically oriented lateral side chamber walls 216 extending between the top chamber wall 212 and the bottom chamber wall 214. In some embodiments, the deposition chamber 202 may have the geometric shape of an elongated rectangular prism, as shown in FIGS. 2 through 4. In other embodiments, the deposition chamber 102 may have another geometric shape.

As discussed subsequently herein in further detail, the deposition chamber 202 includes at least one chamber wall, such as a top chamber wall 212, including one or more selectively configured metrology windows 122 through which radiation 110 emitted by the emitter 107 and/or received by the sensor 108 may pass during in-situ metrology performed using the metrology device 106.

As shown in FIGS. 2 through 4, the deposition chamber 202 may include a plurality of outer structural rib members 217, which may provide structural strength and support to the top chamber wall 212, the bottom chamber wall 214, and the lateral side chamber walls 216. The rib members 217 may be formed from and comprise the same material as the top chamber wall 212, the bottom chamber wall 214, and the lateral side chamber walls 216 (e.g., fused quartz). Each rib member 217 may be bonded to one or more of the top chamber wall 212, the bottom chamber wall 214, and the lateral side chamber walls 216. As known in the art, pressure differentials may be provided across the chamber walls during deposition processes due, for example, to application of a vacuum to the interior of the deposition chamber 202 during deposition processes. The rib members 217 may strengthen the chamber walls and prevent breakage of the chamber walls when pressure differentials are applied across the chamber walls by reducing or increasing the pressure within the deposition chamber 202.

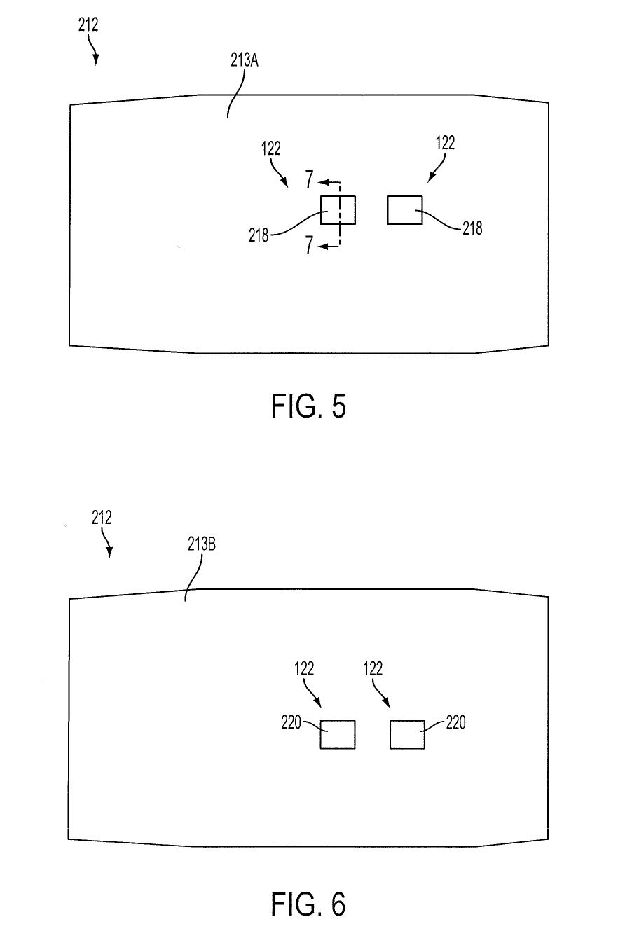

FIG. 5 is a top plan view of the top chamber wall 212 and FIG. 6 is a bottom plan view of the top chamber wall 212 of the deposition chamber 202 of FIGS. 2 through 4. As shown in FIGS. 5 and 6, the top chamber wall 212 includes an outer major surface 213A (FIG. 5) and an inner major surface 213B (FIG. 6). The inner major surface 213B may be oriented at least substantially parallel to the outer major surface 213A. The top chamber wall 212 may be at least generally flat in some embodiments, and may have an at least substantially constant wall thickness between the outer major surface 213A and the inner surface 213B. For example, the wall thickness may be between about 0.1 inch and about 1.0 inch, between about 0.15 inch and about 0.5 inch, or even between about 0.2 inch and about 0.3 inch (e.g., about 0.24 inch). In such embodiments, the outer major surface 213A may be at least substantially planar, and the inner major surface 213B also may be at least substantially planar.

As shown in FIGS. 5 and 6, the top chamber wall 212 includes two metrology windows 122. In other embodiments, the top chamber wall 212 may include only one chamber window 122, or more than two chamber windows 122. In addition, although the deposition chamber 202 of FIGS. 2 through 4 includes chamber windows 122 only in the top chamber wall 212, in other embodiments, zero, one, two, or more metrology windows 122 may be provided in any one or more of the top chamber wall 212, the bottom chamber wall 214, and the side chamber walls 216.

With continued reference to FIGS. 5 and 6, each metrology window 122 includes an outer window surface 218 (FIG. 5) and an inner window surface 220 (FIG. 6). The outer window surface 218 is at least partially circumscribed by the outer major surface 213A, and may be fully circumscribed by the outer major surface 213A as shown in FIG. 5. Similarly, the inner window surface 220 is at least partially circumscribed by the inner major surface 213B, and may be fully circumscribed by the inner major surface 213B as shown in FIG. 6.

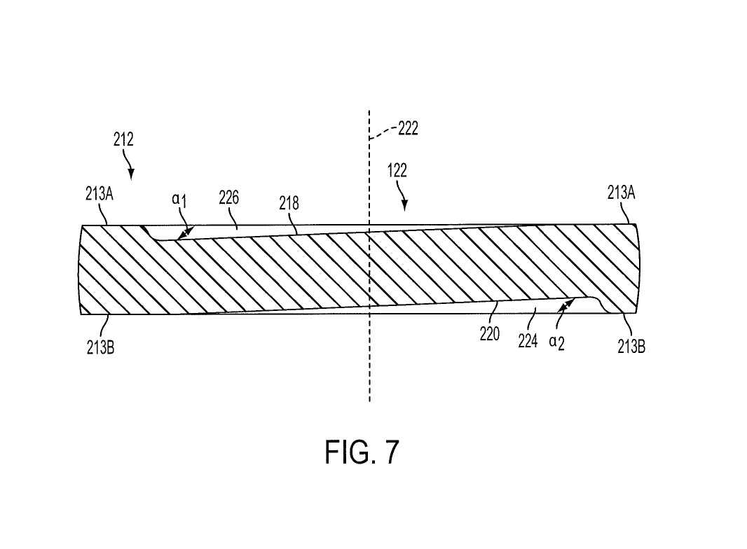

FIG. 7 is an enlarged cross-sectional view of a portion of the top chamber wall 212 taken through a metrology window 122 along section line 7-7 shown in FIG. 5. As shown in FIG. 7, the outer window surface 218 may be oriented at an angle α₁ to the outer major surface 213A, and the inner window surface 220 may be oriented at an angle α₂ to the inner major surface 213B. Further, at least a portion of the inner window surface 220 and at least a portion of the outer window surface 218 may intersect a common axis 222 perpendicular to the outer major surface 213A and the inner major surface 213B. In some embodiments, a common axis 222 may intersect a center of each of the inner window surface 220 and the outer window surface 218.

In some embodiments, the outer window surface 218 and the inner window surface 220 may be at least substantially planar, and they may be oriented parallel to one another, as shown in FIG. 7. In the embodiment of FIGS. 5 through 7, the outer window surface 218 extends along the angle α₁ relative to the outer major surface 213A in the lateral direction (the vertical direction from the perspective of FIGS. 5 and 6), which is transverse to a longitudinal axis extending along the length of the deposition chamber 202 (the horizontal direction from the perspective of FIGS. 5 and 6). Similarly, the inner window surface 220 extends along the angle α₂ relative to the inner major surface 213B in the lateral direction transverse to the longitudinal axis extending along the length of the deposition chamber 202.

As non-limiting examples, each of the angles α₁ and α₂ may be between about 0.01° and about 10.00°, between about 0.10° and about 5.00°, or even between about 1.00° and about 2.50° (e.g., about 2.00°). Further, each of the optical metrology windows 122 may have a length and width (in the planes of FIGS. 5 and 6) that is between about 0.25 inch and about 10.00 inches, between about 0.50 inch and about 5.00 inches, or even between about 1.00 inch and about 2.50 inches (e.g., about 1.44 inches).

As shown in FIG. 7, the outer window surface 218 may extend into the top chamber wall 212 from the outer major surface 213A and define an outer window recess 226 extending into the top chamber wall 212. In some embodiments, the outer window recess 226 may have the shape of a wedge. Similarly, the inner window surface 220 may extend into the top chamber wall 212 from the inner major surface 213B and define an inner window recess 224 extending into the top chamber wall 212. In some embodiments, the inner window recess 224 may have the shape of a wedge. Further, the wedge shape of the outer window recess 226 may be oriented in an opposite direction to the wedge shape of the inner window recess 224, as shown in the embodiment of FIG. 7.

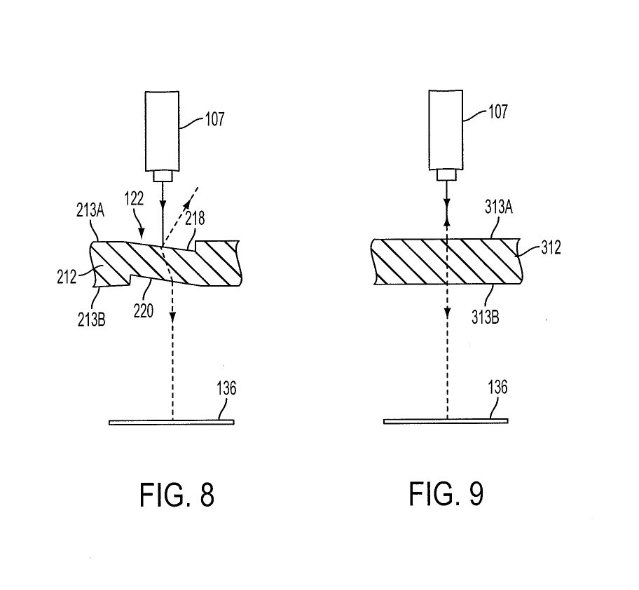

FIGS. 8 and 9 are used to illustrate advantages that may be attained using embodiments of deposition chambers including metrology windows 122 as described herein for performing in-situ metrology.

FIG. 8 schematically illustrates an emitter 107 of a metrology device 106 (see FIG. 1) emitting electromagnetic radiation through a metrology window 122 according to an embodiment of the present disclosure. As shown in FIG. 8, a fraction of the radiation impinging on the outer window surface 218 may be reflected from the outer window surface 218. Due at least in part, however, to the angle α₁ (FIG. 5), the reflected radiation will be directed away from the emitter 107. Although not shown in FIG. 8, a fraction of the radiation passing through the top chamber wall 212 and impinging on the inner window surface 220 (from within the chamber wall 212) may also be reflected from the inner window surface 220. Due at least in part, however, to the angle α₂ (FIG. 6), such reflected radiation also may be directed away from the emitter 107.

FIG. 9 schematically illustrates an emitter 107 of a metrology device 106 (see FIG. 1) emitting electromagnetic radiation through a conventional planar chamber wall 312 of a deposition chamber. As shown in FIG. 9, a fraction of the radiation impinging on the outer major surface 313A of the chamber wall 312 may be reflected from the outer major surface 313A back toward the emitter 107 when the outer major surface 313A is at least substantially perpendicular to the impinging beam of radiation, which may damage the emitter 107, or otherwise adversely interfere with the metrology process. Although not shown in FIG. 9, a fraction of the radiation passing through the chamber wall 312 and impinging on the inner major surface 313B (from within the chamber wall 312) may also be reflected from the inner major surface 313B back to the emitter 107.

By employing metrology windows 122 as described herein in chamber walls of deposition chambers, radiation emitted by an emitter 107 of a metrology device 106 that is reflected from surfaces of the metrology window 122 may be directed away from the emitter 107 so as to prevent the reflected radiation from impinging on the emitter 107 and damaging the emitter 107 or otherwise adversely interfering with the metrology process. Embodiments of the present disclosure may be particularly useful when used in conjunction with metrology systems that include an emitter configured to emit radiation through a chamber wall oriented generally perpendicular to a beam of electromagnetic radiation to be emitted by the emitter.

The embodiments of the invention described above do not limit the scope of the invention, since these embodiments are merely examples of embodiments of the invention, which is defined by the scope of the appended claims and their legal equivalents. Any equivalent embodiments are intended to be within the scope of this invention. Indeed, various modifications of the invention, in addition to those shown and described herein, such as alternate useful combinations of the elements described, will become apparent to those skilled in the art from the description. Such modifications are also intended to fall within the scope of the appended claims.

1. A deposition chamber for a deposition system, comprising:
at least one chamber wall including a transparent material at least substantially transparent to electromagnetic radiation over at least a range of wavelengths, the at least one chamber wall comprising:
an outer major surface;
an inner major surface oriented at least substantially parallel to the outer major surface;
an outer window surface extending from and at least partially circumscribed by the outer major surface, the outer window surface oriented at an angle to the outer major surface; and
an inner window surface extending from and at least partially circumscribed by the inner major surface, the inner window surface oriented at an angle to the inner major surface, at least a portion of the inner window surface aligned with at least a portion of the outer window surface along an axis perpendicular to the outer major surface and the inner major surface.

2. The deposition chamber of claim 1, wherein the outer major surface and the inner major surface are at least substantially planar.

3. The deposition chamber of claim 2, wherein the outer window surface and the inner window surface are at least substantially planar.

4. The deposition chamber of claim 3, wherein the outer window surface and the inner window surface are oriented parallel to one another.

5. The deposition chamber of claim 4, wherein the outer window surface extends into the at least one chamber wall from the outer major surface and defines an outer window recess extending into the at least one chamber wall.

6. The deposition chamber of claim 5, wherein the inner window surface extends into the at least one chamber wall from the inner major surface and defines an inner window recess extending into the at least one chamber wall.

7. The deposition chamber of claim 1, wherein the at least one chamber wall further includes:
another outer window surface extending from and at least partially circumscribed by the outer major surface and separated from the outer window surface by a portion of the outer major surface, the another outer window surface oriented at an angle to the outer major surface; and
another inner window surface extending from and at least partially circumscribed by the inner major surface and separated from the inner window surface by a portion of the inner major surface, the another inner window surface oriented at an angle to the inner major surface, at least a portion of the another inner window surface aligned with at least a portion of the another outer window surface along another axis perpendicular to the outer major surface and the inner major surface.

8. The deposition chamber of claim 1, wherein the deposition chamber comprises a chemical vapor deposition (CVD) chamber.

9. The deposition chamber of claim 8, wherein the deposition chamber comprises a vapor phase epitaxy (VPE) deposition chamber.

10. A method of forming a deposition chamber, comprising:
forming at least one chamber wall including a transparent material at least substantially transparent to electromagnetic radiation over at least a range of wavelengths, wherein forming the at least one chamber wall comprises:
forming an outer major surface of the at least one chamber wall;
forming an inner major surface of the at least one chamber wall oriented at least substantially parallel to the outer major surface;
forming an outer window surface of the at least one chamber wall extending from and at least partially circumscribed by the outer major surface, the outer window surface oriented at an angle to the outer major surface; and
forming an inner window surface of the at least one chamber wall extending from and at least partially circumscribed by the inner major surface, the inner window surface oriented at an angle to the inner major surface, at least a portion of the inner window surface aligned with at least a portion of the outer window surface along an axis perpendicular to the outer major surface and the inner major surface.

11. The method of claim 10, further comprising forming the outer major surface and the inner major surface to be at least substantially planar.

12. The method of claim 11, further comprising forming the outer window surface and the inner window surface to be at least substantially planar.

13. The method of claim 12, further comprising forming the outer window surface and the inner window surface to be oriented parallel to one another.

14. The method of claim 13, further comprising forming the outer window surface to extend into the at least one chamber wall from the outer major surface so as to define an outer window recess extending into the at least one chamber wall.

15. The method of claim 14, further comprising forming the inner window surface to extend into the at least one chamber wall from the inner major surface so as to define an inner window recess extending into the at least one chamber wall.

16. A deposition system, comprising:
a deposition chamber having at least one chamber wall including a transparent material at least substantially transparent to electromagnetic radiation over at least a range of wavelengths, the at least one chamber wall comprising:
an outer major surface;
an inner major surface oriented at least substantially parallel to the outer major surface;
an outer window surface extending from and at least partially circumscribed by the outer major surface, the outer window surface oriented at an angle to the outer major surface; and
an inner window surface extending from and at least partially circumscribed by the inner major surface, the inner window surface oriented at an angle to the inner major surface, at least a portion of the inner window surface aligned with at least a portion of the outer window surface along an axis perpendicular to the outer major surface and the inner major surface; and
at least one metrology device including an emitter and a sensor each located outside the deposition chamber, the emitter configured to emit radiation at one or more wavelengths within the range of wavelengths through each of the outer window surface and the inner window surface of the at least one chamber wall, the sensor configured to receive electromagnetic radiation emitted by the emitter and reflected from a location within the deposition chamber.

17. The deposition system of claim 16, wherein the outer major surface and the inner major surface are at least substantially planar.

18. The deposition system of claim 17, wherein the outer window surface and the inner window surface are at least substantially planar.

19. The deposition system of claim 18, wherein the outer window surface and the inner window surface are oriented parallel to one another.

20. The deposition system of claim 19, wherein the outer window surface extends into the at least one chamber wall from the outer major surface and defines an outer window recess extending into the at least one chamber wall.

21. The deposition system of claim 20, wherein the inner window surface extends into the at least one chamber wall from the inner major surface and defines an inner window recess extending into the at least one chamber wall.
